(19) United States
(12) Patent Application Publication
(10) Pub. No.: US 2003/0042227 A1
(43) Pub. Date: Mar. 6, 2003

(54) Apparatus and method for tailoring an etch profile

(75) Inventor: Steven T. Fink, Mesa, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TOKYO ELECTRON LIMITED, Tokyo (JP)

(21) Appl. No.: 10/230,150

(22) Filed: Aug. 29, 2002

Related U.S. Application Data
(60) Provisional application No. 60/315,368, filed on Aug. 29, 2001.

(51) Int. Cl. C23F 1/00; B44C 1/22; C03C 15/00; H01L 21/306

(52) U.S. Cl. 216/63; 156/345.1; 156/345.43; 156/345.46; 156/345.47; 118/723 E; 216/2

(57) ABSTRACT

A scavenger assembly for use with a plasma etching chamber having an electrode. The scavenger assembly including an adjustable scavenger plug adapted to extend from the electrode into the plasma etching chamber. The adjustable scavenger plug provides a structure for spatially tailoring an etch profile in the plasma etch chamber. Additionally, a method is provided for etching a substrate in a plasma etching chamber. The method includes the steps of providing the substrate on a chuck assembly within the plasma etching chamber, providing an electrode within the plasma etching chamber opposite the chuck assembly, and providing an adjustable scavenger plug extending from the electrode into the plasma etching chamber. The method further includes the step of performing an etching operation on the substrate by spatially tailoring an etch profile in the plasma etch chamber using the adjustable scavenger plug.

### CROSS-REFERENCE TO RELATED APPLICATION

The present application claims priority to U.S. provisional application Serial No. 60/315,368, filed on Aug. 29, 2001, the entire contents of which are herein incorporated by reference.

### BACKGROUND OF THE INVENTION

1. Field of the Invention

The present invention generally relates to etching profiles within plasma etching chambers.

2. Discussion of the Background

The semiconductor and semiconductor manufacturing equipment industry represent a multi-billion dollar industry. Manufacturers of semiconductor integrated circuits (IC) are faced with severe competitive pressure to improve their products and, as a result, improve the processes used to fabricate those products. A major business driver for these manufacturers is the lowering of production costs through the improvement of product throughput, quality and complexity. These improvements are in part a result of improving control over the etch rate as well as etch uniformity within a process. Accordingly, there is a need for a low cost way to tune uniformity, which would provide a manufacturer of semiconductor equipment a competitive edge in the market.

One highly desirable avenue for improvement is in the tool performance where the cost of such improvements is small. The tool performance can be enhanced without driving up the tool cost, thereby increasing the profit margins of the manufacturer of such equipment. In a cyclical industry, such as the semiconductor capital equipment industry, increased profit margins, whether in good times or in bad times, can have a dramatic impact on market penetration, especially during downturns.

In spite of significant advances to date, most etch processes still induce a non-uniform and undesirable etch profile. FIG. 4 depicts a related art processing chamber that typically produces a non-uniform etch rate profile 5, which is superimposed above a wafer 2 mounted in a chuck assembly 1 in FIG. 4. Non-uniformity can be caused by a non-symmetrical exhaust flow, temperature variations, non-uniform plasma chemistry, non-uniform ion density or non-uniform gas supply. These factors can cause variations in the etch rate, selectivity and sidewall profiles in device features on a wafer. What is needed is a way to increase uniformity of an etch profile.

Plasma reactors exploit the formation of chemically active plasma using carefully selected gases. As IC manufacturers push tool vendors to achieve higher etch rates and tighter-controlled etching, the need for balancing the chemical composition of the plasma increases. A high etch rate demands a large volume of plasma at a high density. This is typically done using either inductively or capacitively coupled plasma. For fluorocarbon chemistries in an oxide (i.e. SiO₂) etch, an inductively coupled plasma reactor, and in some instances a capacitively coupled plasma reactor, is highly dissociative, which, if left uncontrolled, results in a large number of fluorine radicals created within the plasma and a poor selectivity of oxide etch to silicon etch (and silicon nitride etch). Moreover, fluorine radicals degrade etch performance characteristics including sidewall profiles, and are thus undesirable. What is needed is a way to achieve a proper chemical balance of plasma.

The etch rate profile 5 illustrated in FIG. 4 is well known, and numerous approaches have been considered with varying degrees of success. One way to adjust the chemistry of plasma is to expose the plasma to a chemically active substance. In many applications, silicon reacts favorably with plasma, for example, if there is atomic fluorine present. Consequently, one known solution is to include a silicon plate 4 in the upper electrode 3 to act as a scavenger, as depicted in FIG. 4. However, the limitation of this approach is that scavenging occurs non-uniformly across the scavenging plate and, furthermore, current practice does not provide for a controllable scavenger.

### SUMMARY OF THE INVENTION

In an effort to provide an improved etch profile, the present invention provides a structure and method of spatially altering the plasma chemistry above the semiconductor wafer.

Accordingly, the present invention advantageously provides a scavenger assembly for use with a plasma etching chamber having an electrode. The scavenger assembly of the present invention includes an adjustable scavenger plug adapted to extend from the electrode into the plasma etching chamber.

Additionally, the present invention advantageously provides a plasma etching apparatus including a plasma etching chamber, a chuck assembly provided within the plasma etching chamber, an electrode provided within the plasma etching chamber, and an adjustable scavenger plug extending from the electrode into the plasma etching chamber.

The present invention further advantageously provides a plasma etching apparatus including a plasma etching chamber, a chuck assembly provided within the plasma etching chamber, an electrode provided within the plasma etching chamber, and means for spatially tailoring an etch profile in the plasma etch chamber.

Furthermore, the present invention advantageously provides a method for etching a substrate in a plasma etching chamber. The method includes the steps of providing the substrate on a chuck assembly within the plasma etching chamber, providing an electrode within the plasma etching chamber opposite the chuck assembly, and providing an adjustable scavenger plug extending from the electrode into the plasma etching chamber. The method further includes the step of performing an etching operation on the substrate by spatially tailoring an etch profile in the plasma etch chamber using the adjustable scavenger plug.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a side cross-sectional view of a plasma etching apparatus according to an embodiment of the present invention;

FIG. 2 is a side cross-sectional view of a plasma etching apparatus according to an alternative embodiment of the present invention;

FIG. 3 is a bottom view of an upper electrode of a plasma etching apparatus according to a further alternative embodiment of the present invention; and

FIG. 4 is a side view of an upper electrode and chuck assembly of a related art plasma etching apparatus.

### DETAILED DESCRIPTION OF THE INVENTION

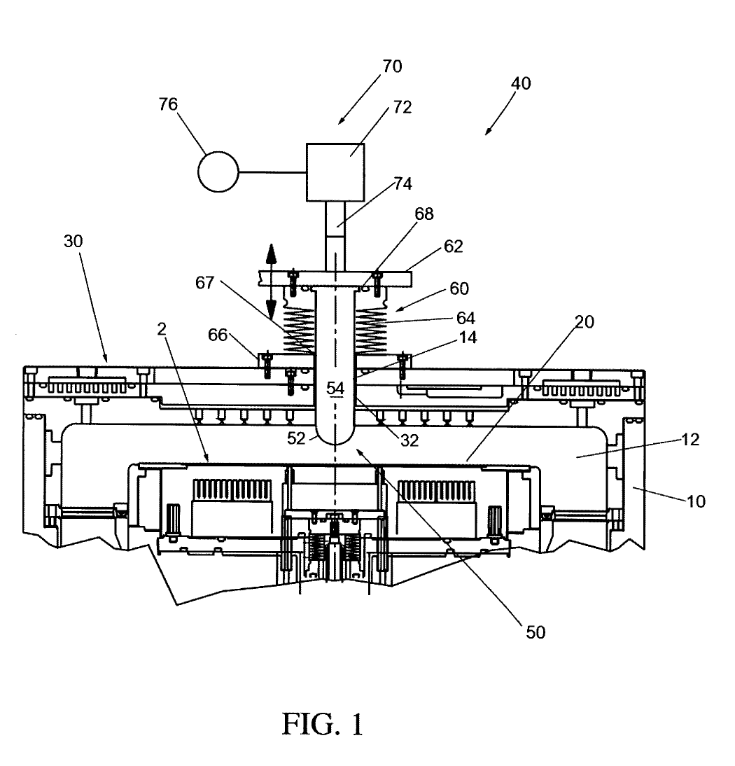

The present invention generally provides a scavenger assembly 40 for use with a plasma etching chamber 10. FIG. 1 depicts a preferred embodiment of the present invention.

The plasma etching chamber 10 defines a processing environment 12 that is generally sealed from the environment outside of the chamber 10. The plasma etching chamber 10 generally has a chuck assembly 20 mounted therein. The chuck assembly 20 is configured to hold a semiconductor wafer or substrate 2 during the plasma processing operation. The plasma etching chamber 10 further includes a grounded upper electrode 30 mounted opposite the chuck assembly 20.

The present invention advantageously includes a scavenger assembly 40. The scavenger assembly 40 generally acts as a means for spatially tailoring an etch profile in the plasma etch chamber 10. The embodiment of the scavenger assembly depicted in FIG. 1 includes a scavenger plug 50 that extends through a hole 32 in the center of the upper electrode 30 and into the processing environment 12 of the plasma etching chamber 10. The scavenger plug 50 is shaped and sized to provide a predetermined etching profile. The scavenger plug 50 is generally a member 52 preferably made of silicon and having a chemically active substance on an exterior surface 54 thereof. The scavenger plug 50 of the preferred embodiment is generally cylindrical in shape, however, any other type of shape can be utilized to achieve a desired etching profile. The scavenger plug 50 can be removed from the scavenger assembly 40 and replaced with a new scavenger plug or a scavenger plug having a different profile (different shape, size, chemical composition, etc.) in order to achieve a desired etching profile.

The scavenger assembly 40 includes a positional adjustment device 70 that is attached to the scavenger plug 50 and is adapted to adjust the position of the scavenger plug 50 by extending and retracting the scavenger plug 50 within the plasma etching chamber 10. The positional adjustment device 70 is located outside of the plasma etching chamber 10. In order to prevent foreign particles from contaminating the processing environment 12 of the plasma etching chamber 10 and in order to prevent the processing environment 12 from exiting the chamber 10, the scavenger assembly 40 further includes a seal assembly 60. The seal assembly 60 is adapted to seal the scavenger plug 50 within a processing environment 12 of the plasma etching chamber 10. The positional adjustment device 70 acts as a means for adjusting an amount of surface area on the scavenger plug 50 and therefore the amount of chemically active substance on the member 52 that is exposed to the processing environment 12 within the plasma etching chamber 10, thereby controlling the etching profile.

The seal assembly 60 includes a movable end plate 62 provided outside of the plasma etching chamber 10 and attached to an end of the scavenger plug 50. The seal assembly 60 also includes a sealed bellows 64 that extends between the movable end plate 62 and a hole 14 in the plasma etching chamber 10. The seal assembly 60 of the preferred embodiment has an O-ring 68 positioned between contacting portions of the bellows 64 and the end plate 62 in order to provide a sealed coupling there between. The bellows 64 is attached to a mounting plate 66 having a hole 67. The mounting plate 66 is mounted to an outer surface of the plasma etching chamber 10 such that the hole 67 of the mounting plate 66, the hole 14 of the chamber 10, and the hole 32 of the electrode 30 are aligned. A portion of the scavenger plug 50 is housed within the sealed assembly 60 and is adapted to extend through the hole 14 in the plasma etching chamber 10.

The positional adjustment device 70 includes a motor 72 and an actuator member 74. The motor 72 is preferably a linear motor, for example, a hydraulic motor, a pneumatic motor, an electric motor with associated gear trains, a stepper motor, piezoelectric stacks, etc. The actuator member 74 is connected between the motor 72 and end plate 62, in order to transfer the motive force from the motor 72 to the end plate 62 and to the scavenger plug 50. A controller 76 is connected to the motor 72 in order to control the motion of the scavenger plug 50.

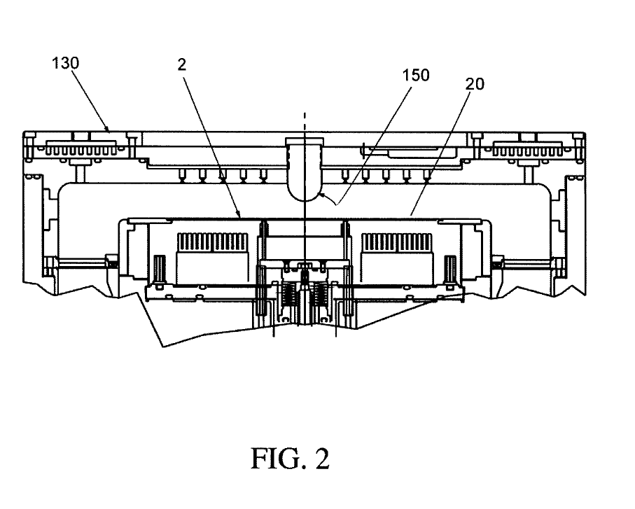

Many variations on the embodiment discussed above are contemplated by the present invention. For example, FIG. 2 depicts an embodiment having a scavenger plug 150 removably attached to an upper electrode 130. The scavenger plug 150 can be attached to the upper electrode 130 using various connection means, such as screw threads, etc. The scavenger plug 150 can be removed and replaced with a scavenger plug of a different shape, size, or chemical composition depending on the desired etching profile for that particular etching processes. Additionally, the scavenger plug 150 can be removed and replaced with a new scavenger plug if the scavenger plug 150 becomes worn or damaged, or the scavenger plug can be replaced with a scavenger plug having a different predetermined profile (different shape, size, chemical composition, etc.) to achieve a desired etching profile.

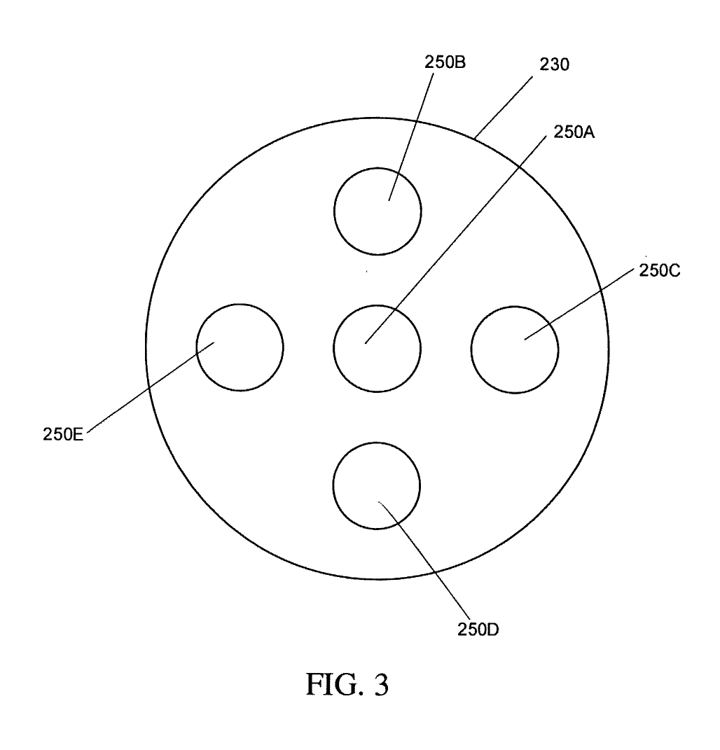

An additional alternative embodiment of the present invention is depicted in FIG. 3. The embodiment of FIG. 3 includes a plurality of scavenger plugs 250A, 250B, 250C, 250D, and 250E. Scavenger plug 250A is positioned at the center of the upper electrode 230 with scavenger plugs 250B, 250C, 250D, and 250E arranged in equally spaced intervals about scavenger plug 250A. The number and arrangement of the scavenger plugs (as well as their shape, size, and chemical composition) can be determined to provide a desired etching profile. The scavenger plugs 250A, 250B, 250C, 250D, and 250E can be mounted in the manner depicted in FIG. 1, in the manner depicted in FIG. 2, or in some other similar manner. If the scavenger assembly depicted in FIG. 1 is utilized with a plurality arrangement of scavenger plugs, then the plugs can all be mounted to a single seal assembly, the plugs can each be mounted on a separate individual seal assembly, or a plural groupings of scavenger plugs can be mounted on separate seal assemblies (e.g. the scavenger plug 250A can be mounted on a first seal assembly and scavenger plugs 250B, 250C, 250D, and 250E can be mounted on a second seal assembly).

The scavenger plug 50 can alternatively be constructed as a probe having a voltage applied thereto. In this configuration the probe is sealed from the processing enviromnent 12 and resides in the plasma etching chamber 10. By controlling the voltage applied to the probe, the plasma chemistry within the plasma etching chamber 10 can be controlled to achieve the desired etching profile. The probe is preferably configured in the same manner as the scavenger assembly 40 depicted in FIG. 1. However, in this embodiment the probe does not need to be moved using the positional adjustment device 70, but rather can be provided in a fixed position since the plasma chemistry can be adjusted by adjusting the voltage applied to the probe.

Accordingly, the positional adjustment device 70 can be eliminated in this embodiment.

Further alternatively, the scavenger plug 50 can be constructed as a cooled permanent magnet. In this configuration the magnet is sealed from the processing environment 12 and resides in the plasma etching chamber 10. By controlling the coolant supply to the permanent magnet, the plasma chemistry within the plasma etching chamber 10 can be controlled to achieve the desired etching profile. The plug is preferably configured in the same manner as the scavenger assembly 40 depicted in FIG. 1. However, in this embodiment the plug does not need to be moved using the positional adjustment device 70, but rather can be provided in a fixed position since the plasma chemistry can be adjusted by adjusting the coolant supply to the permanent magnet. Accordingly, the positional adjustment device 70 can be eliminated in this embodiment.

The present invention advantageously provides a method for etching a substrate in a plasma etching chamber. The method includes the steps of providing the substrate on a chuck assembly within the plasma etching chamber, and providing an electrode within the plasma etching chamber opposite the chuck assembly. The method also provides the step of providing an adjustable scavenger plug extending from the electrode into the plasma etching chamber, for example in the manner described above. The method further includes the step of performing an etching operation on the substrate by spatially tailoring an etch profile in the plasma etch chamber using the adjustable scavenger plug. The step of performing an etching operation by spatially tailoring an etch profile is preferably performed by adjusting an amount of surface area on the scavenger plug that is exposed to a processing environment within the plasma etching chamber, for example, by extending and retracting the scavenger plug within the plasma etching chamber. The spatially tailoring of the etch profile can be controlled through the movement of the scavenger plug based upon predetermined experimental data to achieve a predetermined etch profile, or by using sensors to monitor the progress of the etch profile and making adjustments to the positions of the scavenger plugs based upon the progress of the etch profile.

The present invention advantageously provides one or more consumable scavenger plugs integrated into a plasma reactor electrode. The scavenger plugs of the present invention have predetermined profiles that facilitate scavenging while etching a wafer, thereby providing a greater degree of control over the etching profile. In other words, the etching rate of the etchant on the wafer can be controlled using the scavenging plug in order to ensure a uniform or substantially uniform (or non-uniform if so desired) etch rate profile across the entire surface of the wafer. One embodiment of the present invention that helps achieve such advantageous results is a grounded plasma reactor electrode having a retractable/extendable scavenger plug. The present invention improves process performance.

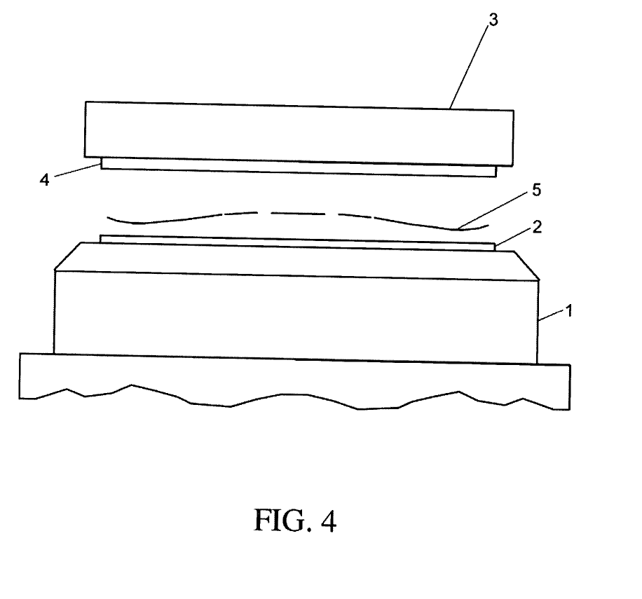

The present invention allows the plasma chemistry and etch profile to be tuned during or between process steps by movement of the plug(s). By providing a scavenger plug in a proximal relationship to a portion of the wafer where the etch rate is faster than the etch rate at the remainder of the wafer, the scavenger plug can increase the etch rate at that slower portion in order to provide a more uniform etch rate along the entire surface of the wafer. For example, the etch rate profile depicted in FIG. 4 indicates that the etch rate at the center of the wafer is faster than the surrounding areas, and therefore the use of a scavenger plug proximate the center of the wafer will make the etch rate profile more uniform. By adjusting the amount of surface area of the scavenger plug is within the processing chamber and by adjusting the proximal relationship to the wafer, the present invention can fine tune the etching rate profile.

This invention is implemented with small additional cost to existing process equipment. Wherever a plug protrudes through the grounded electrode a sealing device is required. Additionally, a vertical motion mechanism may be required, depending on the embodiment. Both of these functions involve extra parts that slightly increase the overall cost of the machine.

It should be noted that the exemplary embodiments depicted and described herein set forth the preferred embodiments of the present invention, and are not meant to limit the scope of the claims hereto in any way.

Numerous modifications and variations of the present invention are possible in light of the above teachings. It is therefore to be understood that, within the scope of the appended claims, the invention may be practiced otherwise than as specifically described herein.

1. A scavenger assembly for use with a plasma etching chamber having an electrode, said scavenger assembly comprising an adjustable scavenger plug adapted to extend from the electrode into the plasma etching chamber.

2. The scavenger assembly according to claim 1, further comprising a positional adjustment device attached to said scavenger plug and adapted to adjust a position of said scavenger plug within the plasma etching chamber.

3. The scavenger assembly according to claim 2, wherein:
said scavenger plug is adapted to extend through a hole in the electrode; and
said positional adjustment device is adapted to extend and retract said scavenger plug within the plasma etching chamber.

4. The scavenger assembly according to claim 2, wherein said positional adjustment device is adapted to be located outside of the plasma etching chamber, said plasma etching apparatus further comprising a seal assembly adapted to seal said scavenger plug within a processing environment of the plasma etching chamber.

5. The scavenger assembly according to claim 4, wherein said seal assembly comprises a movable end plate adapted to be provided outside of the plasma etching chamber and attached to said scavenger plug, and a sealed bellows adapted to extend between said movable end plate and a hole in the plasma etching chamber, wherein a portion of said scavenger plug is housed within said sealed bellows and is adapted to extend through the hole in the plasma etching chamber.

6. The scavenger assembly according to claim 1, further comprising means for adjusting an amount of surface area on said scavenger plug that is exposed to a processing environment within the plasma etching chamber.

7. The scavenger assembly according to claim 6, wherein said means for adjusting is adapted to be located outside of the plasma etching chamber, said scavenger assembly further comprising a seal assembly adapted to seal said scavenger plug within a processing environment of the plasma etching chamber.

8. The scavenger assembly according to claim 7, wherein said seal assembly comprises a movable end plate adapted to be provided outside of the plasma etching chamber and attached to said scavenger plug, and a sealed bellows adapted to extend between said movable end plate and a hole in the plasma etching chamber, wherein a portion of said scavenger plug is housed within said sealed bellows and is adapted to extend through the hole in the plasma etching chamber.

9. The scavenger assembly according to claim 1, wherein said scavenger plug is adapted to be removably attached to the electrode.

10. The scavenger assembly according to claim 1, further comprising at least one additional scavenger plug.

11. The scavenger assembly according to claim 10, further comprising an additional adjustment device for each of said at least one additional scavenger plug.

12. The scavenger assembly according to claim 1, wherein said scavenger plug provides a predetermined etching profile.

13. The scavenger assembly according to claim 1, wherein said scavenger plug is a member having a chemically active substance on an exterior surface thereof.

14. The scavenger assembly according to claim 1, wherein said scavenger plug is a probe having a voltage applied thereto.

15. The scavenger assembly according to claim 1, wherein said scavenger plug is a cooled permanent magnet.

16. A plasma etching apparatus comprising:
a plasma etching chamber;
a chuck assembly provided within said plasma etching chamber;
an electrode provided within said plasma etching chamber; and
an adjustable scavenger plug extending from said electrode into said plasma etching chamber.

17. The plasma etching apparatus according to claim 16, further comprising a positional adjustment device attached to said scavenger plug and adapted to adjust a position of said scavenger plug within said plasma etching chamber.

18. The plasma etching apparatus according to claim 17, wherein:
said scavenger plug extends through a hole in said electrode; and
said positional adjustment device is configured to extend and retract said scavenger plug within said plasma etching chamber.

19. The plasma etching apparatus according to claim 18, wherein said positional adjustment device is located outside of said plasma etching chamber, said plasma etching apparatus further comprising a seal assembly configured to seal said scavenger plug within a processing environment of said plasma etching chamber.

20. The plasma etching apparatus according to claim 19, wherein said seal assembly comprises a movable end plate provided outside of said plasma etching chamber and attached to said scavenger plug, and a sealed bellows extending between said movable end plate and a hole in said plasma etching chamber, wherein a portion of said scavenger plug is housed within said sealed bellows and extends through said hole in said plasma etching chamber.

21. The plasma etching apparatus according to claim 16, further comprising means for adjusting an amount of surface area on said scavenger plug that is exposed to a processing environment within said plasma etching chamber.

22. The plasma etching apparatus according to claim 21, wherein said means for adjusting is located outside of said plasma etching chamber, said plasma etching apparatus further comprising a seal assembly configured to seal said scavenger plug within a processing environment of said plasma etching chamber.

23. The plasma etching apparatus according to claim 22, wherein said seal assembly comprises a movable end plate provided outside of said plasma etching chamber and attached to said scavenger plug, and a sealed bellows extending between said movable end plate and a hole in said plasma etching chamber, wherein a portion of said scavenger plug is housed within said sealed bellows and extends through said hole in said plasma etching chamber.

24. The plasma etching apparatus according to claim 16, wherein said scavenger plug is removably attached to said electrode.

25. The plasma etching apparatus according to claim 16, further comprising at least one additional scavenger plug.

26. The plasma etching apparatus according to claim 25, further comprising an additional adjustment device for each of said at least one additional scavenger plug.

27. The plasma etching apparatus according to claim 16, wherein said scavenger plug provides a predetermined etching profile.

28. The plasma etching apparatus according to claim 16, wherein said scavenger plug is a member having a chemically active substance on an exterior surface thereof.

29. The plasma etching apparatus according to claim 16, wherein said scavenger plug is a probe having a voltage applied thereto.

30. The plasma etching apparatus according to claim 16, wherein said scavenger plug is a cooled permanent magnet.

31. A plasma etching apparatus comprising:
a plasma etching chamber;
a chuck assembly provided within said plasma etching chamber;
an electrode provided within said plasma etching chamber; and
a means for spatially tailoring an etch profile in said plasma etch chamber.

32. The plasma etching apparatus according to claim 31, wherein said means for spatially tailoring an etch profile comprises an adjustable scavenger plug extending from said electrode into said plasma etching chamber.

33. The plasma etching apparatus according to claim 31, wherein said means for spatially tailoring an etch profile comprises a movable, interchangeable scavenging plug protruding through said electrode.

34. The plasma etching apparatus according to claim 31, wherein said means for spatially tailoring an etch profile comprises:
a scavenger plug extending from said electrode into said plasma etching chamber; and
means for adjusting an amount of surface area on said scavenger plug that is exposed to a processing environment within said plasma etching chamber.

35. The plasma etching apparatus according to claim 34, wherein said means for adjusting comprises means for extending and retracting said scavenger plug within said plasma etching chamber.

36. The plasma etching apparatus according to claim 35, wherein said means for extending and retracting is located outside of said plasma etching chamber.

37. The plasma etching apparatus according to claim 36, wherein said means for extending and retracting comprises a linear motor having an actuator attached to said scavenger plug.

38. The plasma etching apparatus according to claim 36, wherein said means for extending and retracting comprises a pneumatic actuator attached to said scavenger plug.

39. The plasma etching apparatus according to claim 36, wherein said means for extending and retracting comprises a hydraulic actuator attached to said scavenger plug.

40. The plasma etching apparatus according to claim 36, wherein said means for extending and retracting comprises piezoelectric stacks attached to said scavenger plug.

41. The plasma etching apparatus according to claim 31, wherein said means for spatially tailoring an etch profile further comprises a plurality of scavenger plugs having various shapes and sizes.

42. A method for etching a substrate in a plasma etching chamber, said method comprising the steps of:
providing the substrate on a chuck assembly within the plasma etching chamber;
providing an electrode within the plasma etching chamber opposite the chuck assembly;
providing an adjustable scavenger plug extending from the electrode into the plasma etching chamber; and
performing an etching operation on the substrate by spatially tailoring an etch profile in the plasma etch chamber using the adjustable scavenger plug.

43. The method according to claim 42, wherein said scavenging plug is movable and protrudes through the electrode.

44. The method according to claim 42, further comprising the step of adjusting an amount of surface area on said scavenger plug that is exposed to a processing environment within said plasma etching chamber.

45. The method according to claim 44, wherein the step of adjusting comprises extending and retracting said scavenger plug within said plasma etching chamber.

46. The method according to claim 42, wherein the step of providing an adjustable scavenger plug further comprises providing a plurality of scavenger plugs having various shapes and sizes.

47. The method according to claim 42, wherein the scavenger plug provides a predetermined etching profile.

48. The method according to claim 42, wherein the scavenger plug is a member having a chemically active substance on an exterior surface thereof.

49. The method according to claim 42, wherein the scavenger plug is a probe having a voltage applied thereto.

50. The method according to claim 42, wherein the scavenger plug is a cooled permanent magnet.
